(19) United States
(12) Patent Application Publication
(10) Pub. No.: US 2011/0316151 A1
(43) Pub. Date: Dec. 29, 2011

(54) SEMICONDUCTOR PACKAGE AND METHOD FOR MANUFACTURING SEMICONDUCTOR PACKAGE

(75) Inventors: Takashi Ozawa, Nagano-shi (JP); Kota Takeda, Nagano-shi (JP)

(73) Assignee: Shinko Electric Industries Co., Ltd., Nagano-shi (JP)

(21) Appl. No.: 13/168,126

(22) Filed: Jun. 24, 2011

(30) Foreign Application Priority Data
Jun. 25, 2010 (JP) 2010-145550

(51) Int. Cl. H01L 23/498; H01L 21/50

(52) U.S. Cl. 257/737; 438/108; 257/E23.068; 257/E21.499

(57) ABSTRACT

A semiconductor package includes a board, an under fill resin layer provided on the board, and a semiconductor chip having a first face and a second face at an opposite side to the first face, the semiconductor chip being flip-chip mounted on the board via the under fill resin layer with the first face facing the board. The semiconductor chip is covered with the under fill resin layer over the first face and from the first face to an edge part of the second face.

### CROSS REFERENCE TO RELATED APPLICATION(S)

This application is based upon and claims the benefit of priority from Japanese Patent Application No. 2010-145550 filed on Jun. 25, 2010, the entire contents of which are incorporated herein by reference.

### TECHNICAL FIELD

The present disclosure relates to a semiconductor package and a method for manufacturing the same, which are effectively applied to a semiconductor package having a PoP (Package on Package) structure.

### RELATED ART

As an art of a semiconductor package for rendering an electronic appliance such as a mobile phone multifunctional, there has been a so-called PoP structure in which a plurality of semiconductor packages are stacked.

In Japanese Patent Publication No. JP-A-2009-146969 (Patent Document 1), there is disclosed a semiconductor package having the PoP structure (hereinafter simply referred to as “a PoP package”) which includes a semiconductor package at a lower side (a mounted side) (hereinafter simply referred to as “a lower package”) and a semiconductor package at an upper side (a mounting side) (hereinafter simply referred to as “an upper package”). In this PoP package in Patent Document 1, a semiconductor chip which is flip-chip mounted on a board of the lower package is provided between a board of the upper package and the board of the lower package.

Moreover, an art related to the flip-chip mounting is disclosed in Japanese Patent Publication No. JP-A-2000-22040 (Patent Document 2).

### PRIOR ART DOCUMENT

### Patent Document

[Patent Document 1]
Japanese Patent Publication No. JP-A-2009-146969

[Patent Document 2]
Japanese Patent Publication No. JP-A-2000-22040

In mounting the semiconductor package having the PoP structure on the electronic appliance, it has required for the semiconductor package to be compact and thin. For this reason, in the PoP package as described in Patent Document 1, each of the lower package and the upper package must be made compact and thin. The lower package is, for example, such that the semiconductor chip is flip-chip mounted on the board. On the other hand, the upper package is, for example, such that the semiconductor chip is mounted by wire bonding on the board of the upper package, and the semiconductor chip and a bonding wire are encapsulated with mold resin.

By the way, the board to be used in the lower package and the upper package is a wiring board which includes, for example, a glass fiber containing epoxy resin, a wiring pattern, etc., and a thermal expansion coefficient of the wiring board is about 14 to 15 ppm/K. The semiconductor chip is formed of, for example, silicon, and its thermal expansion coefficient is about 3 ppm/K.

The wiring board which includes, for example, the glass fiber containing epoxy resin, the wiring pattern, etc. has a higher thermal expansion coefficient than the semiconductor chip, and remarkably expands and shrinks with heat. Therefore, when the semiconductor chip is subjected to heat treatment, for example, on occasion of mounting it, a thermal stress occurs due to a difference in the thermal expansion coefficient between the semiconductor chip and the board. As the results, warpage may occur in the board, in some cases. For example, as shown in FIG. 9, in a board 72 on which a semiconductor chip 71 is mounted, it inevitably happens that the board 72 is warped so as to swell upward.

In the PoP package employing the lower package in which such warpage has occurred, it is considered that reliability of the PoP package is deteriorated. Moreover, it is also considered that the PoP package in which the warpage remains is difficult to be treated in a production process, and a production yield of the PoP package is decreased.

Specifically, in the lower package, warpage may occur, in some cases, due to thermal stress during heat treatment (at about 150 to 200° C., for example) for hardening an under fill resin which is filled into a part (a bonding part) between the board and the semiconductor chip which is flip-chip mounted on the board. The under fill resin is used for decreasing the thermal stress which occurs between the semiconductor chip and the board. However, in case where a thickness of the board of the lower package is reduced to comply with the request for making the PoP package thin, the board is warped, even though such under fill resin is used.

Moreover, warpage may occur in the lower package, in some cases, due to a thermal stress on occasion of reflow heating treatment (for example, at about 250 to 270° C.), when the lower package and the upper package are stacked, and an external connection pad of the lower package is electrically connected to an external connection bump of the upper package. Occurrence of warpage is prevented in the upper package, because the semiconductor chip on the board of the upper package is encapsulated with the mold resin.

For the purpose of preventing occurrence of the warpage of the lower package, it is considered to increase a thickness of the semiconductor chip on the lower package. However, this incurs an increase of cost for the semiconductor chip (silicon), and naturally, production cost for the PoP package is increased.

For the purpose of preventing occurrence of the warpage in the lower package, it is also considered to encapsulate the semiconductor chip on the lower package with mold resin. In case of encapsulating the semiconductor chip with the mold resin in this manner, it is necessary to enlarge a gap between the lower package and the upper package according to a thickness of the increased mold resin. Consequently, a thickness of the PoP package is increased, which is contrary to the request for making the PoP package thin. Moreover, an area corresponding to the mold resin must be secured around the semiconductor chip on the lower package, and accordingly, an area as the PoP package is increased. This is contrary to the request for making the PoP package compact.

Usually, the lower package is formed by dividing a large size board into unit pieces, for example. However, in case of encapsulating the semiconductor chip with the mold resin, the number of the unit pieces to be obtained from the large size board is decreased in order to secure the thickness of the lower package. Further, in case of encapsulating the semiconductor chip with the mold resin, cost for molding dies is high, and the production cost is inevitably increased.

Moreover, in Patent Document 2, a semiconductor element is encapsulated with resin for the purpose of enhancing reliability of a semiconductor device, after the semiconductor element has been mounted via an adhesive film (Reference should be made to a passage [0010] in a specification of Patent Document 2). A potting method (dispense method) is employed for encapsulating with the resin. As a first step, the resin as dam material is applied by dripping it around the semiconductor element so that the resin as inner material may not flow nor spread, then, the resin as the inner material is applied by dripping it on the semiconductor element, and thereafter, these resins are hardened.

However, only by forming the resin as the dam material and the resin as the inner material simply by employing the potting method, it is difficult to control thicknesses and shapes of the resins, after the semiconductor element has been encapsulated with the resins. For this reason, the art disclosed in Patent Document 2 is not effective to comply with the request for making the semiconductor package thin and compact. Specifically, as for the semiconductor package to be made thin and compact, it is necessary to prevent warpage of the semiconductor package, by applying other arts than the art disclosed in Patent Document 2, and to enhance reliability of the semiconductor package.

### SUMMARY

Exemplary embodiments of the invention provide a semiconductor package and a manufacturing for the same which can improve the reliability of the semiconductor package.

A semiconductor package according to an exemplary embodiment includes:

a board;

an under fill resin layer provided on the board; and

a semiconductor chip having a first face and a second face at an opposite side to the first face, the semiconductor chip being flip-chip mounted on the board via the under fill resin layer with the first face facing the board,

wherein the semiconductor chip is covered with the under fill resin layer over the first face and from the first face to an edge part of the second face.

A method for manufacturing a semiconductor package according to an exemplary embodiment includes:

(a) preparing a semiconductor chip having a first face and a second face at an opposite side to the first face;

(b) preparing a board;

(c) preparing a bonding tool having a facing face, and a contact face which is projected from the facing face and smaller than a size of the semiconductor chip;

(d) forming an under fill resin layer on the board;

(e) sucking the semiconductor chip by the bonding tool, while the facing face faces the second face of the semiconductor chip and the contact face is kept in contact with a center part of the second face; and

(f) flip-chip mounting the semiconductor chip on the board via the under fill resin layer in a state which the semiconductor chip is sucked by the bonding tool,

wherein

in the (f) flip-chip mounting the semiconductor chip, the semiconductor chip is pushed into the under fill resin layer, whereby the under fill resin layer covers the edge part of the second face from the first face.

According to exemplary embodiments of the invention, it is possible to provide a semiconductor package and a manufacturing for the same which can improve the reliability of the semiconductor package.

### BRIEF DESCRIPTION OF THE DRAWINGS

FIG. 1 shows a sectional view of a PoP package in a first embodiment.

FIG. 2 shows a plan view of an essential part of the PoP package shown in FIG. 1.

FIG. 3 shows a sectional view of a process in the manufacturing method of the PoP package shown in FIG. 1.

FIG. 4 shows a sectional view of a process subsequent to the process shown in FIG. 3 in the manufacturing method of the PoP package.

FIG. 5 shows a sectional view of a process subsequent to the process shown in FIG. 4 in the manufacturing method of the PoP package.

FIG. 6 shows a sectional view of a process subsequent to the process shown in FIG. 5 in the manufacturing method of the PoP package.

FIG. 7 shows a sectional view of a process subsequent to the process shown in FIG. 6 in the manufacturing method of the PoP package.

FIG. 8 shows a sectional view of a PoP package in a second embodiment.

FIG. 9 shows a view explaining warpage occurred in a board on which a semiconductor chip is mounted.

### DETAILED DESCRIPTION

Now, embodiments of the invention will be described in detail, referring to the drawings. It is to be noted that in all the drawings for describing the embodiments, members having the same function are denoted with the same reference numerals, and repetitive descriptions of the members will be omitted, in some cases.

### Embodiment 1

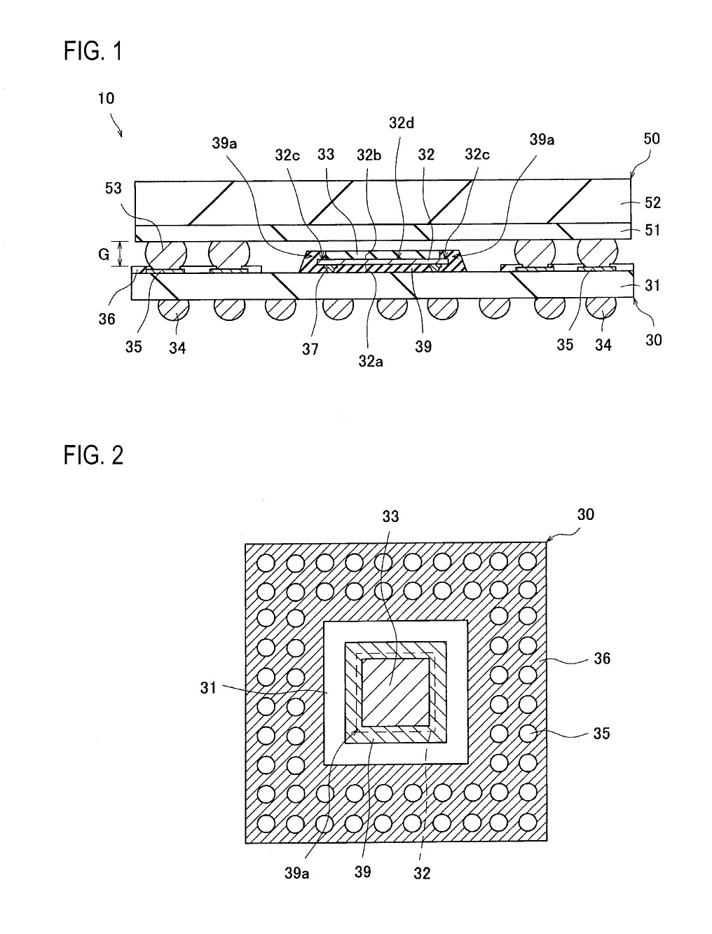

At the beginning, structure of a PoP package 10 in this embodiment will be described. FIG. 1 shows a sectional view of the PoP package 10 in this embodiment. The PoP package 10 includes a semiconductor package at a lower side (a mounted side) (hereinafter, simply referred to as “a lower package”) 30 and a semiconductor package at an upper side (a mounting side) (hereinafter, simply referred to as “an upper package”) 50. Moreover, FIG. 2 shows a plan view of the lower package 30 as an essential part of the PoP package 10. It is to be noted that a part of FIG. 2 is hatched for clarifying description and positional relation, and a position of a semiconductor chip 32 is shown by a broken line.

As shown in FIG. 1, the upper package 50 includes a board 51, semiconductor chips (not shown) which are mounted on a chip mounting face of the board 51, a mold resin 52 which is provided on the board 51 for encapsulating the semiconductor chips, and external connection bumps 53 which are provided on a back face of the board 51 at an opposite side to the chip mounting face and electrically connected to the semiconductor chips.

The board 51 which is an upper board to be facing a board 31 of the lower package 30 is, for example, a wiring board having a wiring pattern or the like which is not shown. The semiconductor chips in plurality, for example, are mounted on the board 51, and in this case, the upper package 50 is formed as a multi chip package (MCP).

Moreover, the external connection bumps 53 are, for example, solder balls, and a gap G (a separation distance) is formed between the lower package 30 and the upper package 50 according to a height of the solder balls. The gap G is limited to a size (height) of the external connection bumps 53, and a pitch between the adjacent external connection bumps 53 is limited by the size of the external connection bumps 53. A width of the gap G is about 200 μm, for example.

Further, as shown in FIG. 1, the lower package 30 includes a board 31, an under fill resin layer 39 which is formed on the board 31, and a semiconductor chip 32 which has a main face (an element forming face) 32a and a back face 32b at an opposite side thereto. The semiconductor chip 32 is flip-chip mounted on the board 31 with the main face 32a facing the board 31 via the under fill resin layer 39.

The semiconductor chip 32 has a rectangular shape in a plan view and a thickness of about 50 μm, for example, and external connection bumps 37 are formed on the main face 32a thereof. This semiconductor chip 32 is flip-chip mounted on the board 31, and the external connection bumps 37 provided on the main face 32a are electrically connected to the external connection pads, which are not shown, of the board 31. In FIG. 2, the semiconductor chip 32 (shown by a broken line) is mounted in a center part of the board 31.

Moreover, the external connection pads (not shown) corresponding to the external connection bumps 37 are formed on the board 31. In addition, the lower package 30 includes external connection bumps 34 which are provided on a back face of the board 31 at an opposite side to the chip mounting face, and electrically connected to the semiconductor chip 32. It is to be noted that these external connection bumps 34 may be substituted with external connection pads.

The board 31 which is the lower board and faces the board 51 of the upper package 50 is, for example, a wiring board having a wiring pattern or the like which is not shown. This board 31 has external connection pads 35 which are provided at a side facing the upper package 50, and an insulating layer 36 (solder resist, for example) which is formed with openings for exposing the external connection pads 35. In FIG. 2, a plurality of the external connection pads 35 are arranged in two rows along an edge part of the board 31.

As described above, in the PoP package 10, the external connection bumps 53 which are provided on the board 51 at a side facing the board 31 are connected to the external connection pads 35 which are provided on the board 31 at the side facing the board 51, and the gap G is formed between the board 31 and the board 51. In this gap G, there are provided the semiconductor chip 32 and the under fill resin layer 39.

In the lower package 30 of the PoP package 10, the semiconductor chip 32 is flip-chip mounted on the board 31. The board 31 is, for example, a wiring board which includes glass fiber containing epoxy resin, the wiring pattern, etc. and its thermal expansion coefficient is about 14 to 15 ppm/K. Moreover, the semiconductor chip 32 is formed of silicon, for example, and its thermal expansion coefficient is about 3 ppm/K. In this manner, there is a difference in the thermal expansion coefficient between the board 31 and the semiconductor chip 32, and hence, the board 31 tends to be warped due to thermal stress.

In view of the above, in this embodiment, the semiconductor chip 32 is covered with the under fill resin layer 39 over the main face 32a and from the main face 32a to an edge part 32c of the back face 32b. In this manner, it is possible to prevent warpages of the lower package 30 and of the PoP package 10 including the same, and it is also possible to improve reliability of the lower package 30 and the PoP package 10.

The under fill resin layer 39 provided on the board 31 has a swelled part 39a which is swelled over the back face 32b of the semiconductor chip 32 which is mounted on the board 31. This swelled part 39a also covers the edge part 32c of the back face 32b of the semiconductor chip 32. As the results, the resin layer (the under fill resin layer 39) is provided not only on the main face 32a of the semiconductor chip 32 but also on the back face 32b, and hence, it is possible to prevent the warpage of the board 31.

Moreover, in the lower package 30 in this embodiment, the resin layer is not provided on the edge part 32c of the back face 32b, separately from the resin layer on the main face 32a, but the semiconductor chip 32 is covered with the under fill resin layer 39 which is integrally formed over the main face 32a and from the main face 32a to the edge part 32c of the back face 32b. Therefore, in case where the under fill resin layer 39 is integrally provided, the warpage of the board 31 can be more effectively prevented, as compared with a case where the resin layers are separately provided.

Besides, in the lower package 30 in this embodiment, an inner resin layer 33 is provided so as to fill a center part 32d of the back face 32b of the semiconductor chip 32 which is surrounded with the under fill resin layer 39 in the edge part 32c. This inner resin layer 33 is formed of epoxy resin, for example, provided with silica filler for decreasing thermal expansion, and its thermal expansion coefficient is about 20 ppm/K.

As described above, an entirety of the semiconductor chip 32 is encapsulated with the inner resin layer 33 and the under fill resin layer 39. As the results, in case where the inner resin layer 33 is also provided, it is possible to further prevent the warpage of the board 31, as compared with a case where only the under fill resin layer 39 is provided.

For the purpose of preventing the warpage of the board 31, the thermal expansion coefficient of the inner resin layer 33 can be optionally selected. In case where the thermal expansion coefficient of the inner resin layer 33 is higher than that of the board 31, this functions so as to cancel the warpage of the board 31 due to the thermal stress, and hence, the warpage of the board 31 (the lower package 30) can be prevented.

Moreover, in the lower package 30, the thermal expansion coefficients of the inner resin layer 33 and the under fill resin layer 39 are adjusted, specifically, made different from each other according to a state of the warpage of the board 31. Mainly for decreasing the thermal stress due to the difference in the thermal expansion coefficient between the semiconductor chip 32 and the board 31, the under fill resin layer 39 which has the higher thermal coefficient (about 55 to 60 ppm/K, for example) than the board 31 is used, and mainly for decreasing the thermal expansion, the inner resin layer 33 which has the lower thermal expansion coefficient (about 20 ppm/K, for example) than the under fill resin layer 39 is used.

Moreover, in the PoP package 10, insulation between the lower package 30 and the upper package 50 must be secured except connection parts between the external connection pads 35 and the external connection bumps 53. In view of the above, the under fill resin layer 39 and the inner resin layer 33 which are not conductive but have insulation properties are used, and thus, insulation performance can be reliably secured.

As the thicknesses of the swelled part 39a of the under fill resin layer 39 and the inner resin layer 33 which cover the semiconductor chip 32 are increased more and more, the warpage of the board 31 can be prevented. However, in the PoP package 10, upper limits of the thicknesses of the swelled part 39a and the inner resin layer 33 are restricted by a size of the gap G between the lower board 31 and the upper board 51. Therefore, in this embodiment, the semiconductor chip 32, the under fill resin layer 39, and the inner resin layer 33 are provided in the gap G in the PoP package 10. Because the under fill resin layer 39 and the inner resin layer 33 having the insulation properties are used, the insulation performance can be secured, even though the inner resin layer 33 which is provided on the back face of the semiconductor chip 32 comes into contact with the board 51 of the upper package 50.

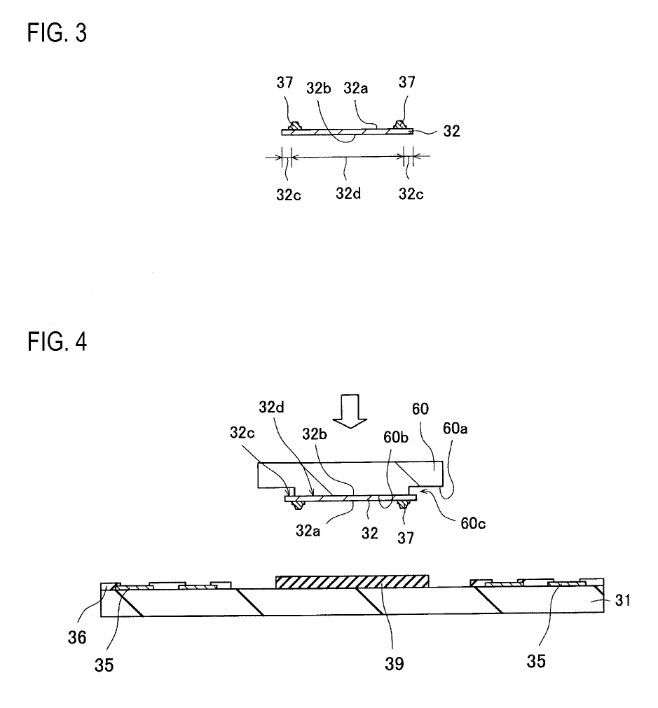

Then, a method for manufacturing the PoP package 10 in this embodiment will be described. Hereinafter, a method for producing the lower package 30 will be mainly described. As a first step, as shown in FIG. 3, the semiconductor chip 32 which has the main face 32a and the back face 32b at an opposite side thereto is prepared. In FIG. 3, there are shown the edge part 32c in the back face 32b of the semiconductor chip 32, and the center part 32d which is surrounded with the edge part 32c.

Then, as shown in FIG. 4, a bonding tool 60 having an opposed face 60a which is facing the back face 32b of the semiconductor chip 32, and a contact face 60b which is projected from the opposed face 60a to come into contact with the back face 32b of the semiconductor chip 32 and smaller than a chip size of the semiconductor chip 32 is prepared. Specifically, the bonding tool 60 has a projected part 60c which is projected from the opposed face 60a.

Moreover, as shown in FIG. 4, the board 31 which is provided with the external connection pads 35 is prepared. This board 31 is, for example, a wiring board, and formed with an insulating layer (solder resist) 36 as a surface protecting layer for the board. The external connection pads 35 are exposed from this insulating layer 36. Thereafter, the under fill resin layer 39 is formed on the board 31. In case where the resin in a form of a film, for example, is used as the under fill resin layer 39, it would be sufficient that the resin is pasted to the board 31, or in case where the resin in a liquid form is used, it would be sufficient that the resin is applied to the board 31 in advance, and kept in a half dried state (B stage). In case where the resin in form of a film is used, a desired shape can be made easily by cutting the film and thus, a volume, size and shape of the under resin layer can be managed and adjusted easily.

Then, the semiconductor chip 32 is sucked by the bonding tool 60, while the contact face 60b is kept in contact with the center part 32d of the back face 32b of the semiconductor chip 32. In this embodiment, the contact face 60b of the bonding tool 60 is kept in contact with only the center part 32d of the semiconductor chip 32, but is not kept in contact with the edge part 32c of the semiconductor chip 32.

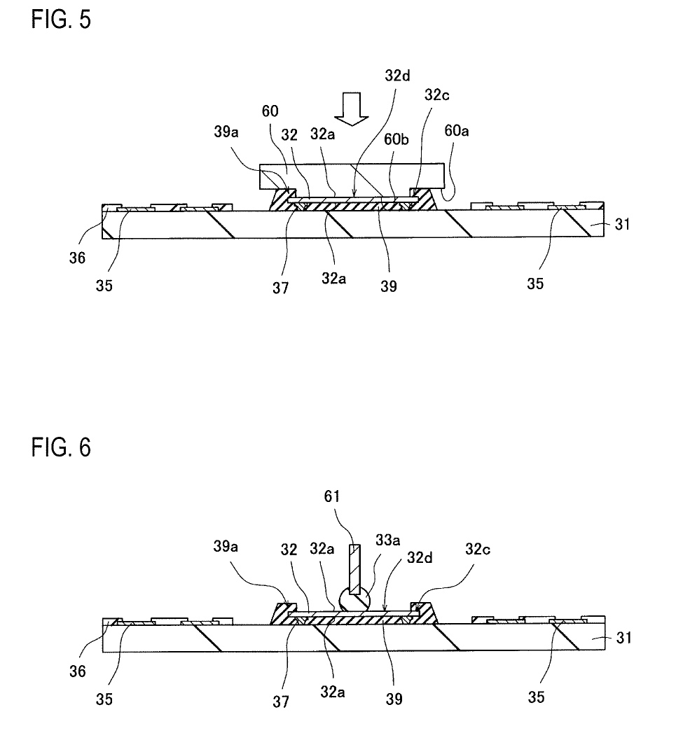

Subsequently, as shown in FIG. 5, the semiconductor chip 32 is flip-chip mounted on the board 31 via the under fill resin layer 39, in a state which the semiconductor chip 32 is sucked by the bonding tool 60. On this occasion, the semiconductor chip 32 is pushed into the under fill resin layer 39, whereby the swelled part 39a is formed in the under fill resin layer 39, and further, the under fill resin layer 39 covers the edge part 32c of the back face 32b of the semiconductor chip 32 from the main face 32a. As the results, the semiconductor chip 32 is covered with the under fill resin layer 39 over the main face 32a and from the main face 32a to the edge part 32c of the back face 32b.

In a process for flip-chip mounting the semiconductor chip 32 on the board 31, the under fill resin layer 39 which has covered the back face 32b of the semiconductor chip 32 is pressed with the opposed face 60a of the bonding tool 60. Because the under fill resin layer 39 which is being swelled is pressed with the opposed face 60a of the bonding tool 60, it is possible to adjust a height of the swelled part 39a of the under fill resin layer 39.

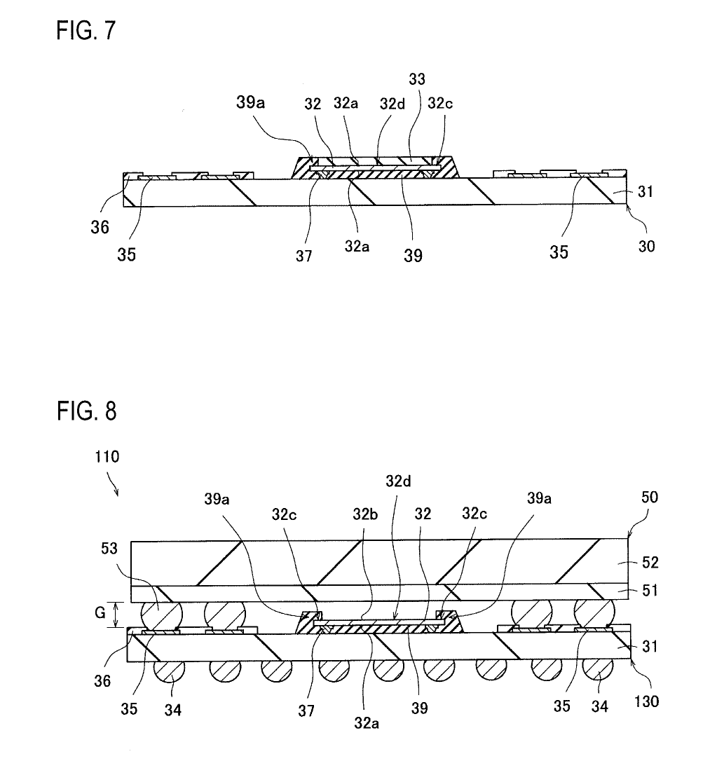

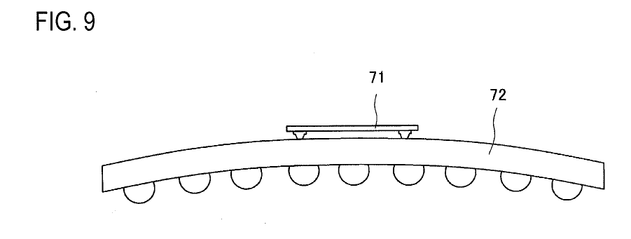

Then, as shown in FIG. 6, the center part 32d which is surrounded with the under fill resin layer 39 (the swelled part 39a) in the edge part 32c of the semiconductor chip 32 is filled with a resin 33a in a liquid form by potting, using a syringe 61. Thereafter, the resin 33a in a liquid form is hardened with heat thereby to form the inner resin layer 33, as shown in FIG. 7. In this manner, the lower package 30 is nearly completed. In this embodiment, the inner resin layer 33 is formed by potting; however, a resin in a form of a film may used.

In a process for forming the inner resin layer 33, the swelled part 39a functions as a dam member so that the resin 33a may not flow out from the center part 32d. Moreover, surface tension is applied to the resin 33a in a liquid form thereby to restrain the resin 33a from flowing out across the swelled part 39a. Because the height of the swelled part 39a is adjusted by the projected part 60c of the bonding tool 60, as described above, a height of the resin 33a in a liquid form, that is, a height (thickness) of the inner resin layer 33 is also adjusted.

Moreover, as shown in FIG. 1, the upper package 50 having the board 51 which is provided with the external connection bumps 53 is prepared. Then, the board 51 of the upper package 50 is stacked on the board 31 of the lower package 30, and they are forwarded into a reflow furnace at about 250 to 270° C., for example, thereby to connect the external connection bumps 53 to the external connection pads 35 by reflow treatment. In this manner, the PoP package 10 is nearly completed.

According to such manufacturing art, it is possible to turn the under fill resin layer 39 around the edge part 32c of the back face 32b of the semiconductor chip 32 from the main face 32a, as described above referring to FIG. 5. As the results, the warpage of the lower package 30 and the PoP package 10 including the same can be prevented, and so, it is possible to enhance their production yields.

Moreover, as described above referring to FIG. 5, because the under fill resin layer 39 which is being swelled is pressed with the opposed face 60a of the bonding tool 60, it is possible to adjust the height of the swelled part 39a of the under fill resin layer 39. As the results, it is possible to provide the semiconductor chip 32 and the under fill resin layer 39 so as to be contained inside the gap G of the PoP package 10.

Moreover, because the height of the swelled part 39a of the under fill resin layer 39 is adjusted, as described above referring to FIG. 6, the height of the resin 33a in a liquid form, that is, the height (thickness) of the inner resin layer 33 can be also adjusted. As the results, it is possible to provide the semiconductor chip 32, the under fill resin layer 39, and the inner resin layer 33 so as to be contained inside the gap G in the PoP package 10.

Moreover, because the warpage of the lower package 30 is prevented, it is possible to prevent the warpage of the PoP package 10, and to enhance its production yield, even in case where the board 51 of the upper package 50 is stacked on the board 31 of the lower package 30, and they are subjected to the reflow treatment.

### Embodiment 2

In the above described Embodiment 1, a case where the inner resin layer 33 is provided on the back face 32b (the center part 32d) of the semiconductor chip 32 in the lower package 30 of the PoP package 10 has been described. However, in this embodiment, a case where the inner resin layer 33 is not provided will be described. It is to be noted that the description of the other structures is omitted, because they are the same as those structures which have been described in Embodiment 1.

As shown in FIG. 8, the inner resin layer 33 as shown in FIG. 1 is not provided in the lower package 130 of the PoP package 110 in this embodiment. Even in such a structure, the semiconductor chip 32 is covered with the under fill resin layer 39 over the main face 32a and from the main face 32a to the edge part 32c of the back face 32b. Specifically, the resin layer (the under fill resin layer 39) is provided on the edge part 32c of the back face 32b of the semiconductor chip 32. As the results, it is possible to prevent the warpage of the lower package 130 and the PoP package 110 including the same, and also possible to enhance reliability of the packages.

While certain embodiments have been described, these embodiments have been presented by way of example only, and are not intended to limit the scope of the invention. Indeed, the novel package and method described herein may be embodied in a variety of other forms; furthermore, various omissions, substitutions and changes in the form of the package and method, described herein may be made without departing from the sprit of the invention. The accompanying claims and their equivalents are intended to cover such forms or modifications as would fall within the scope and sprit of the invention.

What is claimed is:

1. A semiconductor package comprising:
a board;
an under fill resin layer provided on the board; and
a semiconductor chip having a first face and a second face at an opposite side to the first face, the semiconductor chip being flip-chip mounted on the board via the under fill resin layer with the first face facing the board,
wherein the semiconductor chip is covered with the under fill resin layer over the first face and from the first face to an edge part of the second face.

2. The semiconductor package as claimed in claim 1, further comprising:
a resin layer provided on a center part of the second face which is surrounded with the under fill resin layer on the edge part,
wherein the semiconductor chip is encapsulated with the under fill resin layer and the resin layer.

3. The semiconductor package as claimed in claim 2, wherein the under fill resin layer and the resin layer are different from each other in thermal expansion coefficient.

4. The semiconductor package as claimed in claim 1, further comprising:
an upper board stacked on the board as a lower board,
wherein an external connection bump provided on the upper board at a side facing the lower board is connected to an external connection pad provided on the lower board at a side facing the upper board and a gap is formed between the upper board and the lower board, and
the semiconductor chip and the under fill resin layer are provided in the gap.

5. A method for manufacturing a semiconductor package comprising:
(a) preparing a semiconductor chip having a first face and a second face at an opposite side to the first face;
(b) preparing a board;
(c) preparing a bonding tool having a facing face, and a contact face which is projected from the facing face and smaller than a size of the semiconductor chip;
(d) forming an under fill resin layer on the board;
(e) sucking the semiconductor chip by the bonding tool, while the facing face faces the second face of the semiconductor chip and the contact face is kept in contact with a center part of the second face; and
(f) flip-chip mounting the semiconductor chip on the board via the under fill resin layer in a state which the semiconductor chip is sucked by the bonding tool,
wherein
in the (f) flip-chip mounting the semiconductor chip, the semiconductor chip is pushed into the under fill resin layer, whereby the under fill resin layer covers the edge part of the second face from the first face.

6. The method for manufacturing a semiconductor package as claimed in claim 5, wherein
in the (f) flip-chip mounting the semiconductor chip, the under fill resin layer which covers the second face is pressed with the facing face of the bonding tool.

7. The method for manufacturing a semiconductor package as claimed in claim 5, further comprising:
(g) filling the center part of the second face which is surrounded with the under fill resin layer on the edge part with resin by potting, thereby to form a resin layer, after the (f) flip-chip mounting the semiconductor chip.

8. The method for manufacturing a semiconductor package as claimed in claim 5, further comprising:
(h) stacking an upper board on the board as a lower board, and connecting an external connection bump provided on the upper board to an external connection pad provided on the lower board, by reflow treatment.
